(19) United States
(12) Patent Application Publication
(10) Pub. No.: US 2015/0195934 A1
(43) Pub. Date: Jul. 9, 2015

(54) PROTECTIVE CONTAINER HOUSING

(71) Applicants: PAUL PRIVETTE, GAINESVILLE, FL (US); KRISTIN A. PRIVETTE, GAINESVILLE, FL (US)

(72) Inventors: PAUL PRIVETTE, GAINESVILLE, FL (US); KRISTIN A. PRIVETTE, GAINESVILLE, FL (US)

(21) Appl. No.: 14/149,276

(22) Filed: Jan. 7, 2014

(51) Int. Cl. H05K 5/02; H05K 5/03; H05K 7/20; B65D 51/00

(52) U.S. Cl. CPC H05K 5/0247; B65D 51/00; H05K 5/03; H05K 5/0217; H05K 7/20

(57) ABSTRACT

A protective hutch to hold and protect the contents of a container. The protective hutch has a drop cover that can be automatically controlled by the action of inserting or removing a container from within and provides single-handed operation. A linear actuator holds the drop cover open and is operably attached to a first lever. A container inserted into the protective hutch will contact the first lever causing the linear actuator to move and allow the drop cover to move into a position that protects the mouth of the container. An adjustable floor panel provides a further advantage of making the device adaptable to variable size containers.

### BACKGROUND OF INVENTION

It seems to be universal fact that an open container is bound to have something fall, fly, or drop into it. Whether it is a cup of coffee or a can of paint, it seems almost impossible sometimes to keep the contents uncontaminated. Obviously, this problem is worse in areas where airborne contaminates are more prevalent.

The usually solution to this problem has been to attach some device to the container that covers the mouth and that can be removed to give access to the interior of the container or the contents. When the contents of the container need to be accessed reasonably often, a temporary or removable cover can be used. The problem with most of these temporary covers is that they often require some action on the part of the user to displace the cover from the container mouth to access the contents of the container. Further, these temporary displaceable covers usually remain attached to the container, which can make the container difficult or awkward to hold or use.

Another issue is the lack of universality of most container covers. Many container covers are designed to operate with a specific type of container, and often with a container having a specific type of lid or opening to which the cover can attach. For example, beverage can covers are well-known. They often necessitate the can being inserted into some type of holder to which the cover is attached or the cover has some type of attachment to the can. Usually the cover can be manually placed over the can opening to protect the beverage inside. If cover devices are made more universal, they often do not provide adequate protection or still require manual placement over or on a container.

There are situations in which it would be more convenient for one cover to be useful with different types of containers. It would also be beneficial if the cover could be activated or deactivated by an automatic process that did not require direct manipulation by a user. This would allow the cover to be used in a greater variety of situations and even one-handed, if necessary. It would also allow use of any desirable container, like a favorite cup or glass, and still operate to protect the contents.

### BRIEF SUMMARY

In accordance with embodiments of the subject invention, the problem of placing a temporary cover over a container is solved by a protective container hutch into which containers of various sizes or shapes can be inserted, whereupon a drop cover is activated to further protect the contents of the container. The container hutch of the subject invention can protect the contents of a container from stray or airborne materials and is useful under a variety of conditions. The advantages of the device of the subject invention, which will become apparent from the following disclosure, reside in the ability to use any container, including non-standardized containers, and the cover mechanism being controlled automatically by insertion and removal of a container from the hutch. The protective hutch can be removably or permanently affixed to a structure, or it can be a stand-alone device, making it tabletop portable.

Advantageously, the protective hutch can have an opening that provides easy access to insert or remove a container just by grasping or holding the container and pulling it out of the hutch. A drop cover can be a front panel that, when activated, covers a portion of the hutch opening near the container mouth when a container is inserted. The hutch can be adjustable to ensure that the drop panel, when activated or put in place, is at the proper level to protect the container mouth. Activation of the drop cover can be achieved by insertion of a container through the front entryway in the hutch, whereby the container activates an actuator and causes the drop cover to be put in place over the entryway. Ideally, the actuator mechanism in the hutch is biased to hold the drop cover away from the front entryway, so the hutch is always open until such time that a container is inserted and activates the actuator to cause the drop cover to move into a protective position. The act of removing the container from the hutch deactivates the activator. Thus, this bias of the actuator causes the drop cover to be moved out of position over the front entryway automatically or simultaneously with removal of the container from the hutch. Ideally, the entire process can be conducted single-handedly.

Specific embodiments can include one or more of mechanisms for adjusting the size of the interior of the hutch, a flexible or partially flexible drop cover, water and/or weather resistant actuator components, and mechanisms for controlling the temperature of a container and or the contents therein when inserted into a hutch. Thus, the subject invention successfully addresses the above described disadvantages associated with the previously known temporary container covering devices and methods, and provides additional attributes and advantages, which have not been realized by these known devices.

It should be noted that this Brief Summary is provided to generally introduce the reader to one or more select concepts described below in the Detailed Disclosure in a simplified form. This Summary is not intended to identify key and/or required features of the claimed subject matter. Other aspects and further scope of applicability of the present invention will also become apparent from the detailed descriptions given herein. It should be understood, however, that the detailed descriptions, while indicating preferred embodiments of the invention, are given by way of illustration only, since various changes and modifications within the spirit and scope of the invention will become apparent from such descriptions. The invention is defined by the claims below.

### BRIEF DESCRIPTION OF DRAWINGS

In order that a more precise understanding of the above recited invention can be obtained, a more particular description of the invention briefly described above will be rendered by reference to specific embodiments thereof that are illustrated in the appended drawings. The drawings presented herein may not be drawn to scale and any inferences or references to dimensions in the drawings or the following description are specific to the embodiments disclosed. Any variations of these dimensions that will allow the subject invention to function for its intended purpose are considered to be within the scope of the subject invention. Thus, understanding that these drawings depict only typical embodiments of the invention and are not therefore to be considered as limiting in scope, the invention will be described and explained with additional specificity and detail through the use of the accompanying drawings in which:

FIG. 1A is a left front perspective view of an embodiment of the subject invention with a container inserted therein and the drop cover in a closed position.

FIG. 1B is a left front perspective view of an embodiment, showing the platform partially extracted from the cover.

FIG. 1C is a left, front perspective view showing two alternative embodiments of a flexible drop cover. One embodiment (left side) is a flexible material that wraps around to the side wall of the cover and the other embodiment (right side) is a layer of bristles that covers only the entryway.

FIG. 1D is a left, front perspective view showing an alternative embodiment of a rigid or semi-rigid drop cover that forms part of the sidewalls.

FIG. 1E is a left, front perspective view showing an alternative embodiment of a rigid or semi-rigid drop cover that can flip or rotate towards the roof of the cover.

FIG. 2A is a left elevation view of an embodiment having a spring biased switch-activated linear actuator to control the drop cover.

FIG. 2B is a left elevation view of an embodiment with the left sidewall of the hutch removed, to show the interior components of the device. In this figure, a container is shown activating an actuator mechanism to close the drop cover.

FIG. 3 is a left elevation view of an embodiment, with the left sidewall of the hutch removed, to show the interior components of the device. In this figure, a container is shown being removed from the hutch causing deactivation of the linear actuator to open the cover.

FIG. 4 is a left elevation view of an alternative embodiment shown with the left side of the hutch removed, to show the interior components of the device. In this figure, a container is shown as it deactivates an alternative embodiment of an actuator mechanism. Also shown is a platform having a heating element.

FIG. 5 is a front elevation view of an embodiment of the subject invention with a container inserted therein and the drop cover closed.

FIG. 6 is a front elevation view of an embodiment, which demonstrates the floor panel moved to a higher position in the hutch to accommodate a smaller container.

FIG. 7A is a left elevation view of an embodiment having a spool that aids in controlling the linear actuator.

FIG. 7B is a left elevation view, shown with the left sidewall of the hutch removed to show the interior components of an embodiment of a floor panel attached to a first lever.

FIG. 8 is a left elevation view, shown with the left sidewall of the hutch removed to show the interior components and an alternative embodiment of a heating element in the floor panel.

### DETAILED DISCLOSURE

The subject invention describes embodiments of a protective hutch for receiving and protecting a container, in particular, for covering the mouth and interior of a container. More specifically, the subject invention provides one or more embodiments of a protective hutch, or similar device, capable of protecting the mouth and contents of a container, particularly a container with an open mouth.

The following description will disclose that the subject invention is particularly useful in areas where water, objects, particles, substances, or other materials are airborne and susceptible to being deposited into an open container. However, a person with skill in the art will be able to recognize numerous other uses that would be applicable to the devices and methods of the subject invention. The subject application describes, and many of the terms herein relate to, a use for protecting the contents of an open beverage container, such as a coffee cup or beverage can. However, modifications that make the device useful for other applications will be apparent to a person with skill in the art and having benefit of the subject disclosure and are contemplated to be within the scope of the present invention.

In the description that follows, a number of terms are used in relation to embodiments of the device of the subject invention. In order to provide a clear and consistent understanding of the specification and claims, including the scope to be given such terms, the following definitions are provided.

The term “container” as used in relation to the subject invention is merely for literary convenience. This term should not be construed as limiting the invention in any way. The devices, apparatus, methods, techniques and/or procedures of the subject invention could be utilized with any type of container, including, but not limited to, a cup, a beverage container or can, a glass, a bowl, a plate, or other non-food related container, such as, for example, a paint pot, ink well, oil container, etc.

Also, as used herein, and unless otherwise specifically stated, the terms “operable communication,” “operable connection,” “operably connected,” “operatively engaged,” “cooperatively engaged” and grammatical variations thereof mean that the particular elements are connected in such a way that they cooperate to achieve their intended function or functions. The “connection” or “engagement” may be direct, or indirect, physical or remote.

Finally, reference is made throughout the application to the “upper end” and “lower end.” As used herein, the upper end is that end located above or over a container disposed within the protective housing. Conversely, the lower end of the device is that end located below or beneath a container disposed within the protective housing.

The present invention is more particularly described in the following examples that are intended to be illustrative only since numerous modifications and variations therein will be apparent to those skilled in the art. As used in the specification and in the claims, the singular “a,” “an” and “the” include plural referents unless the context clearly dictates otherwise.

Reference will be made to the attached figures on which the same reference numerals are used throughout to indicate the same or similar components. With reference to the attached figures, which show certain embodiments of the subject invention, it can be seen that the subject invention comprises a protective hutch 10 having an upper end 100, a lower end 200, a front side 150 and a rear side 250. In general, the protective hutch 10 comprises a cover 20 to which a floor panel 60 can be operably engaged and a drop cover 80 on the front side and at or about the upper end. The drop cover can project over at least a portion of the entryway 22 in the front side. The cover interior 25 can be configured with one or more supports 27, which can be engaged with the floor panel to hold it in place as it supports a container.

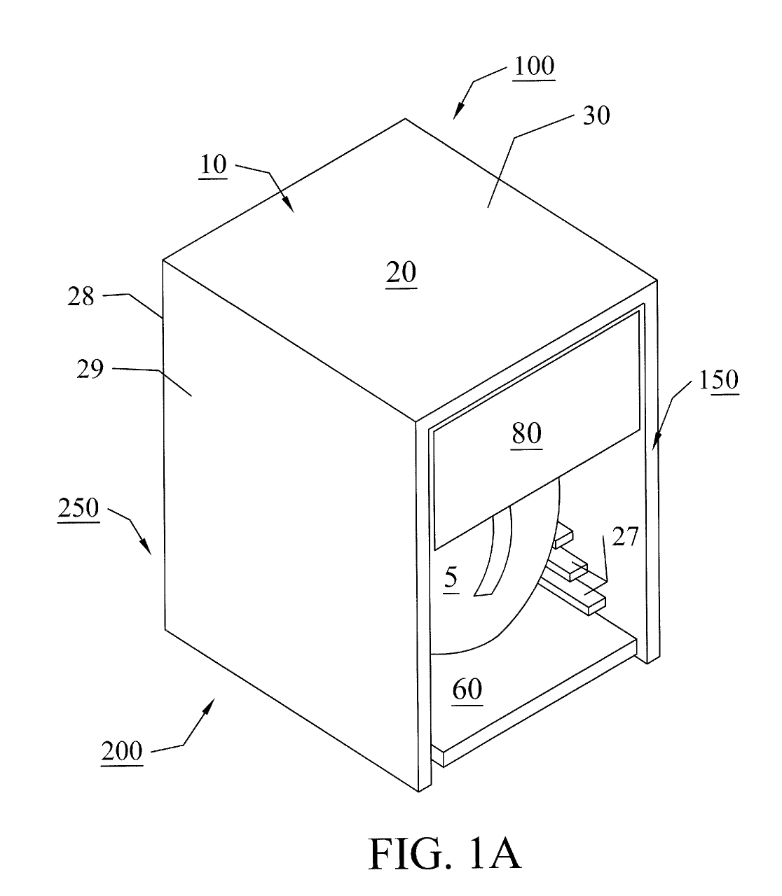

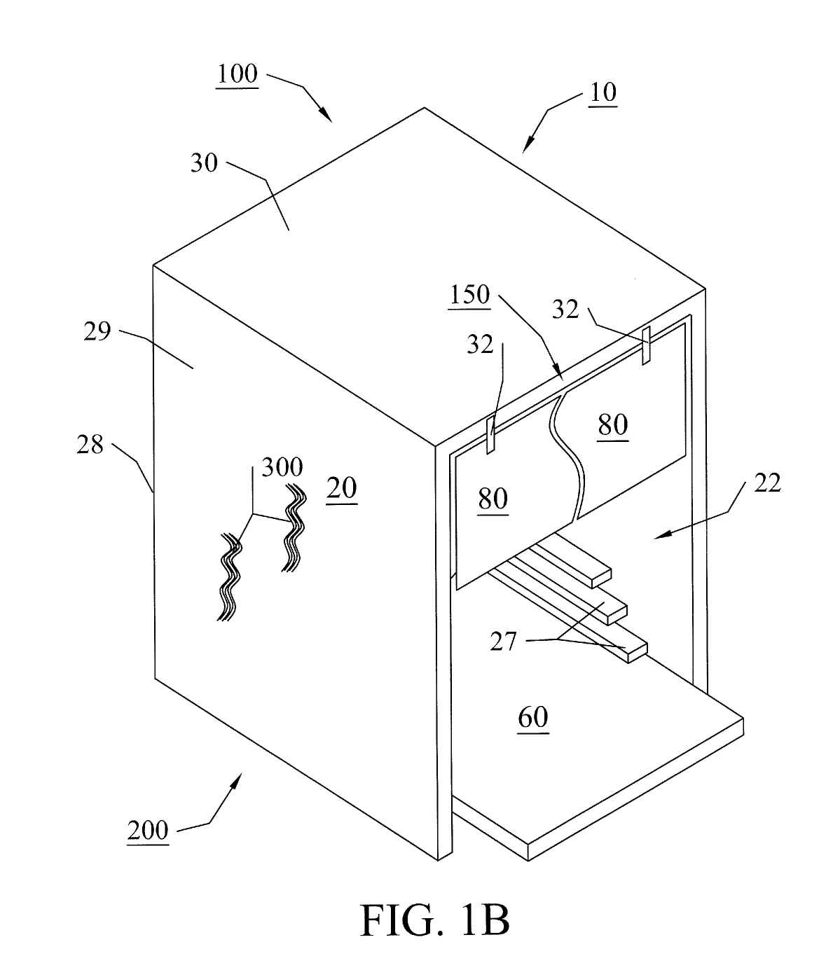

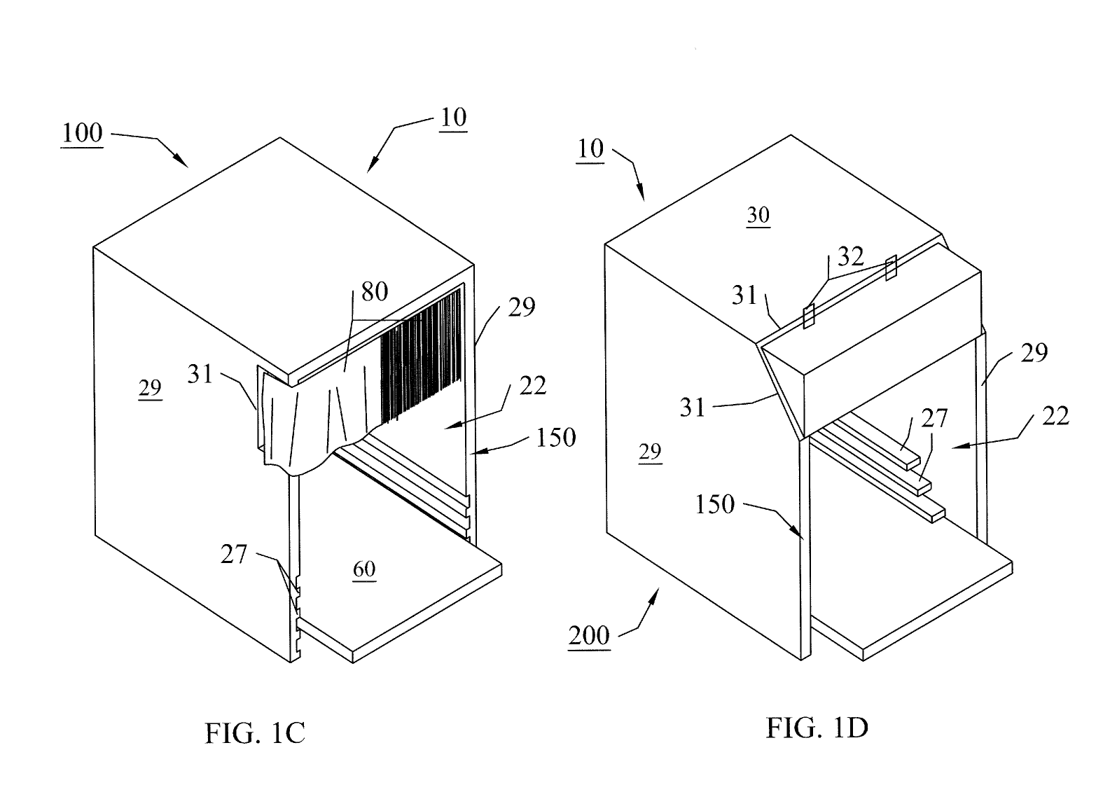

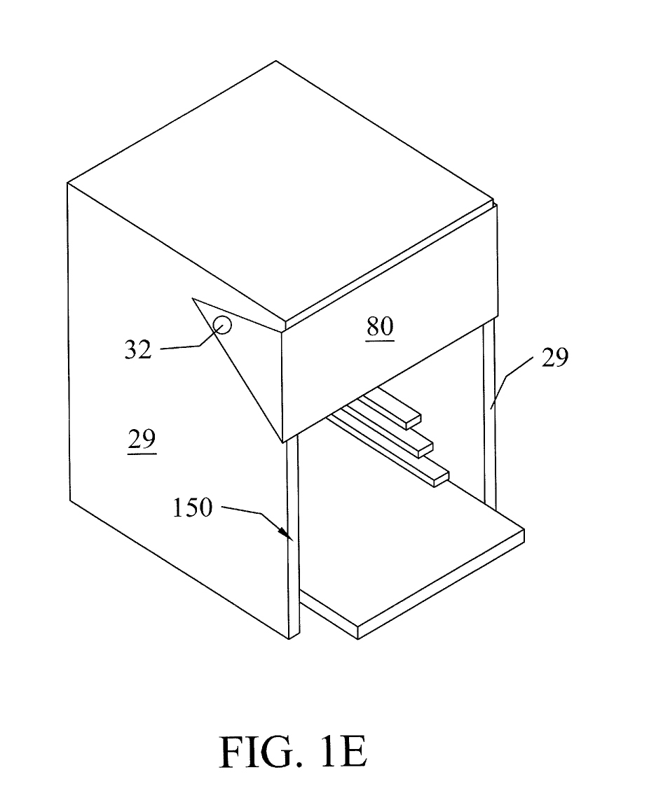

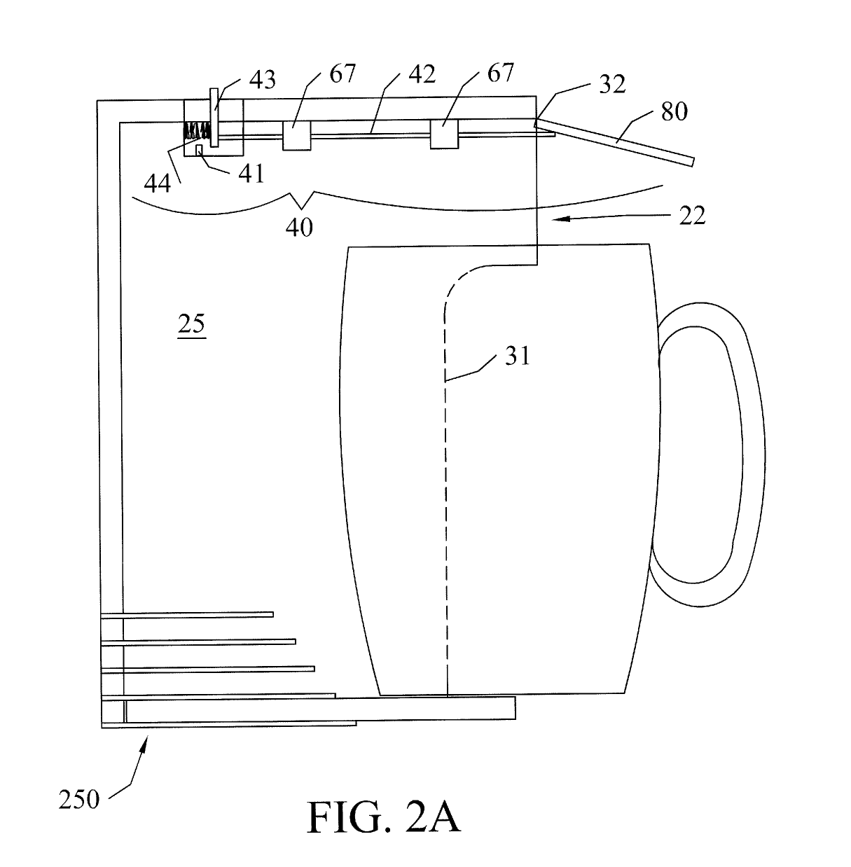

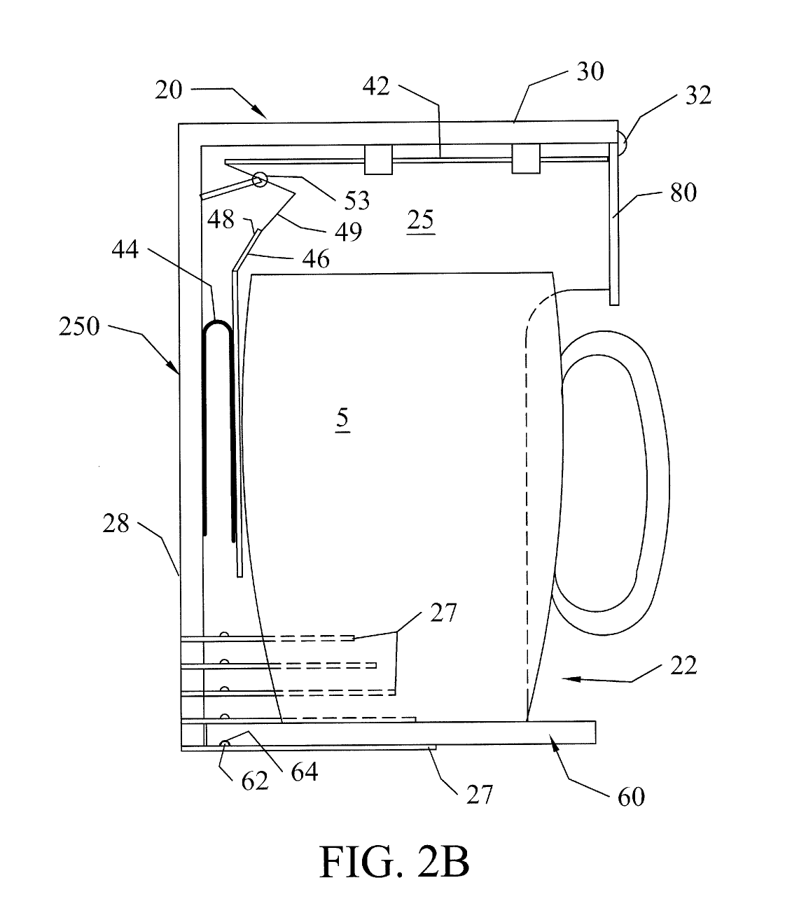

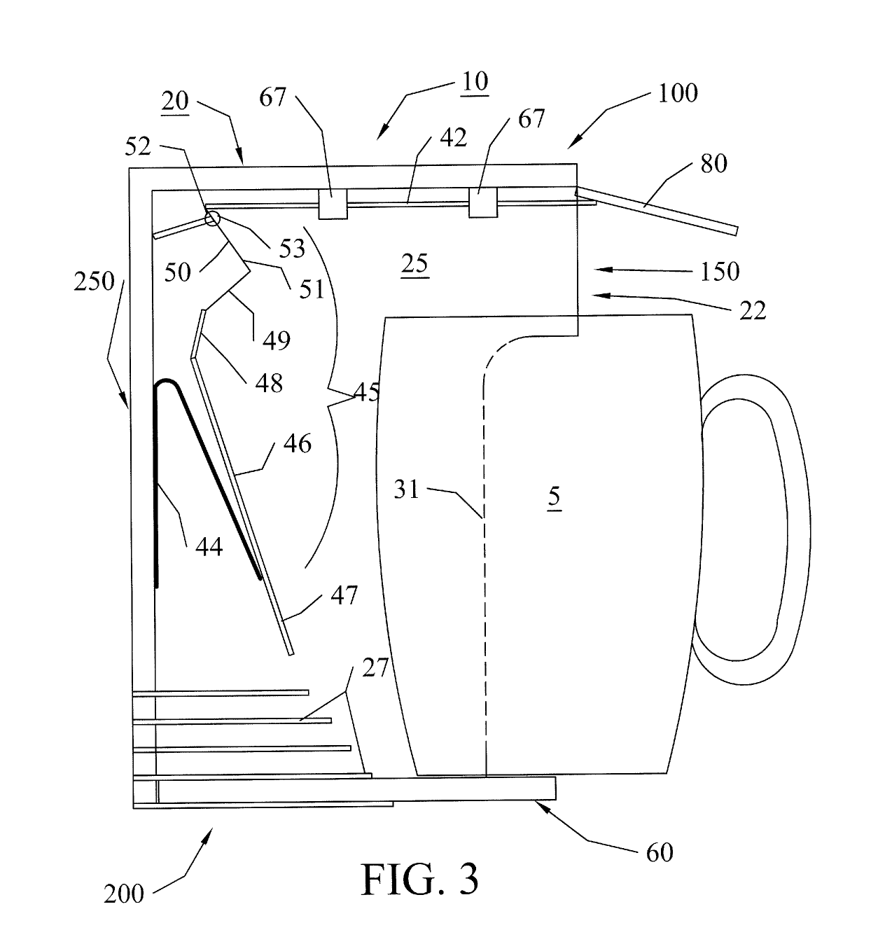

With regard to the figures, it can be seen that the cover 20 of a protective hutch 10 can be generally designed to overlap at least the opening of a container 5. In one embodiment, the cover is a walled enclosure that defines an interior space 25 into which a container 5 can be inserted, as shown, for example, in FIGS. 1A and 2B. In one embodiment, the cover has one or more of a rear wall 28, a side wall 29, and a roof 30, as shown, by way of non-limiting example, in FIGS. 1A and 1B. The cover, including the walls and roof thereof, can be formed into any shape or style that is conducive for use as described herein. Typically, the cover is fully enclosed, such that airborne material cannot penetrate the cover. However, this is not required and the cover can be open on one or more sides, or have one or more slots, cuts, or windows within the walls or roof. By way of non-limiting example, a sidewall can have a cut-out 31 that is contiguous with the entryway 22 that allows for easier grasping of a container within the cover. FIGS. 2A and 3 illustrate one example of this embodiment. In one embodiment, the cover is generally square or rectangular in shape, as illustrated in FIGS. 1A and 1B. In an alternative embodiment, the cover is generally round or oval in shape. Ideally, the shape and dimensions of the cover 20 provide an interior space 25 into which a container can be inserted sufficiently that the entire mouth of the container can be covered or protected. Thus, any of a variety of other shapes or configurations for a cover are also possible. Such variations in cover shape, style, dimensions, or other features that provide the same function, in substantially the same way with substantially the same result are within the scope of this invention.

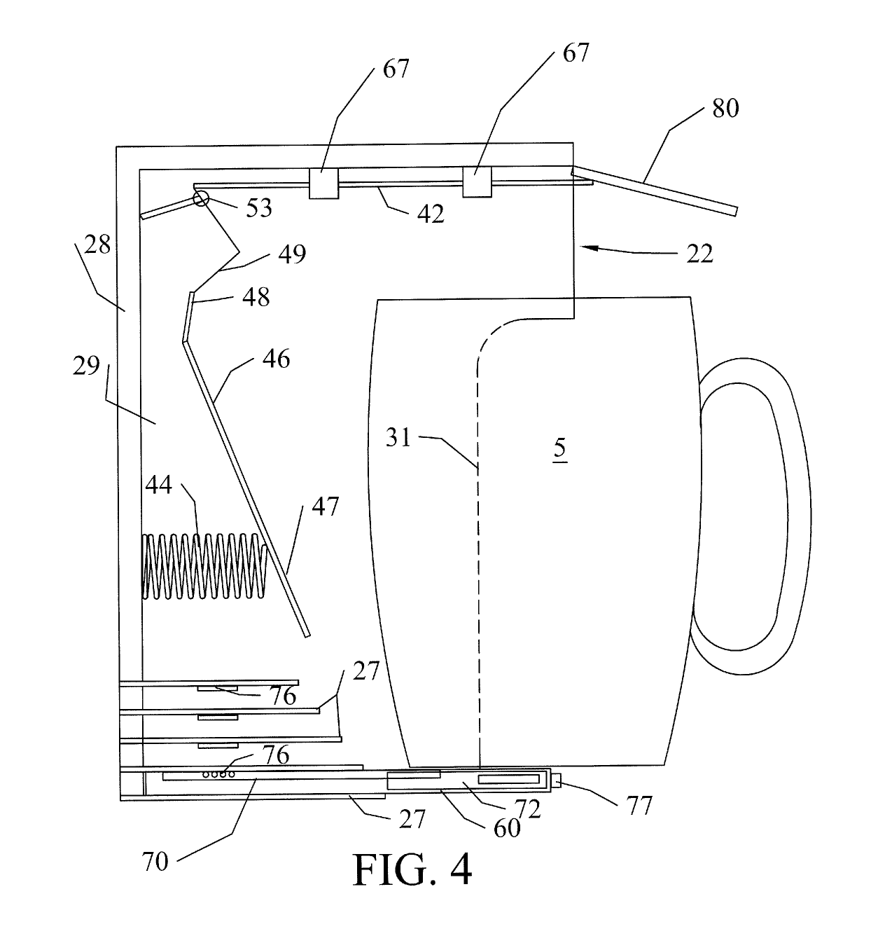

In order that a container can be inserted into the interior space 25, the front side 150 of the cover can have an entryway 22. In one embodiment, the majority of the front side 150 comprises an entryway 22, such as shown, for example, in FIGS. 3 and 4. The advantage of employing an entryway that encompasses substantially all of the front side, or at least enough of the front side to allow insertion of a container, is that it can enable quick and convenient access to the container. Preferably, the container can be inserted without having to tilt or tip it to one side in any way. This necessitates the entryway being sufficiently large enough to accommodate most containers. However, the mouth of the container can be exposed by the open front side, allowing airborne material to more easily migrate into the container. While the roof 30 and any sidewalls 29 can provide significant protection against falling or floating airborne material, wafting or floating airborne material could still find a way into the interior space and the container mouth.

In one embodiment, a protective drop cover 80 is operably connected to the cover 20, so that it extends over the entryway 22. In a further embodiment, the drop cover protects the mouth of a container within the interior space 25 by blocking access to a portion of the upper end 100 of the entryway 22. As mentioned above, one advantage of the protective hutch 10 is the immediate access provided to insert or remove a container. Thus, the drop cover will not, ideally, block or cover the entire entryway and, further, will preferably not inhibit grasping of a container to move it in or out of the protective hutch. In one embodiment, a drop cover blocks between approximately 10% to approximately 75% of the entryway, including a portion at the upper end. In a particular embodiment, a drop cover blocks between approximately 10% and approximately 35% of the upper end of the entryway. In a specific embodiment, a drop cover blocks between approximately 10% and approximately 25% of the upper end of the entryway.

In one embodiment, the drop cover 80 is a non-rigid, semi-rigid, or bendable material or one or more devices or objects that flex, fold, bend, or will otherwise give way when a container is inserted or pushed through the entryway. FIG. 1C illustrates embodiments of a drop cover that are flexible or can be displaced. The left side of the drop cover in this figure is a sheet of flexible material that acts as a curtain and the right side is a plurality of bristles dense enough to form a sufficient barrier to protect the mouth of a container. The drop cover can drop down, fall or bend back into place, or otherwise return to a position that directs it towards the lower end and covers the mouth of a container in the interior space 25. Any of a variety of devices or materials can be used as a flexible drop cover. Such variations that perform the same function, in substantially the same way, with substantially the same result, as those described above, are within the scope of this invention.

As described above, a drop cover can function to protect some portion of the entryway in the front side 150 of a cover 20. In an alternative embodiment, a drop cover can extend around the front face and towards one or both of the sidewalls 29. A drop cover can lie against one or both of the sidewalls. Alternatively, a side wall 29 can have a cut-out 31 or be otherwise shaped to have an open portion contiguous with the entryway 22. A drop cover could then also cover this open portion of the sidewall. FIG. 1C illustrates an embodiment where one side of the drop cover extends around to the sidewall of the cover. Also shown in FIG. 1C is an example of a sidewall having a cut-out 31, contiguous with the entryway 22, which the drop cover 80 can extend around to also cover and protect. In use, a container inserted through the front face can distort the drop cover material until the container is within the interior space 25, at which point the drop cover will return to an original configuration, i.e., one covering at least a portion of the front side and, if present, any other open portion in a sidewall.

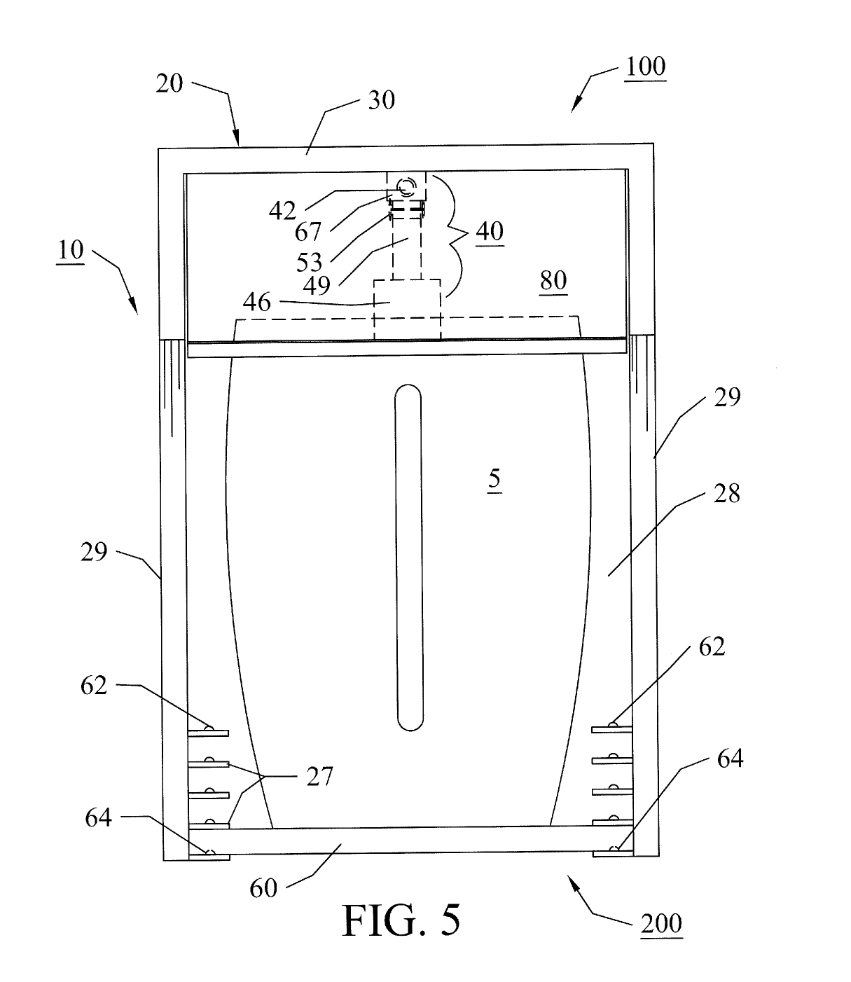

In an alternative embodiment, the drop cover 80 can be rigid or semi-rigid. With this embodiment, the drop cover 80 is also operably connected, such as by a rotatable attachment, to the cover, so as to protect front side entryway. A rigid or semi-rigid drop cover can alternatively extend from the roof 30 and cover at least a portion of the upper end of the entryway 22 on the front side 150 between the side walls 29, to act as a barrier across a portion of the upper end of the front side. FIGS. 1B and 5 illustrate an example of this embodiment.

In an alternative embodiment, the drop cover 80 can extend around the front side 150 and towards one or both of the sidewalls, similarly to the embodiment described above. A portion of the drop cover can overlap one or both of the sidewalls. In a further embodiment, the drop cover can have a rotatable attachment 32 to a sidewall, such that it can rotate or “flip” upwards towards the roof 30, as shown in the Example in FIG. 1E. In still another embodiment, a side wall can be modified with a cut-out 31 or open portion that can be contiguous with the front side 150. In a further alternative, the roof could also have a cut-out 31, or be otherwise retracted or shortened at the front side, such as shown, for example, in FIG. 1D. The drop cover 80 could then be configured, as shown in the example in FIG. 1D, to also cover this cut-out 31 in the sidewall and/or the roof 30.

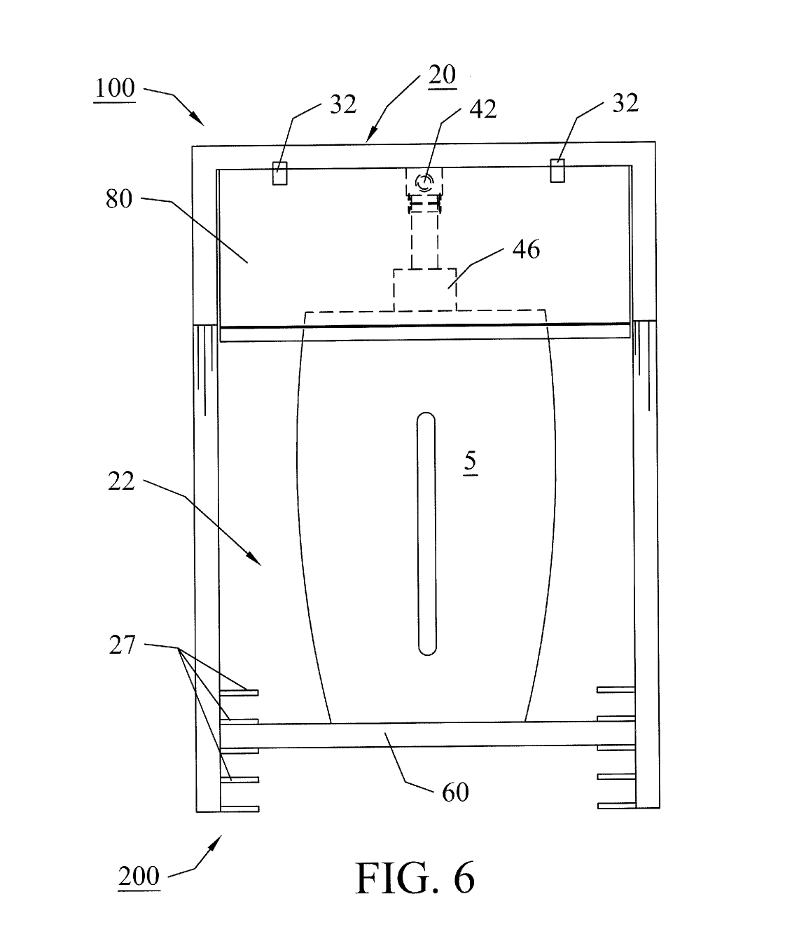

Any of a number of cover 20 and drop cover 80 configurations can be used for both a flexible, semi-flexible or semi-rigid or rigid cover. While the embodiments described above mention flexible or rigid embodiments, alternative embodiments could employ some combination thereof, such as shown, for example, in FIG. 6. In this embodiment, the upper end 100 of the drop cover is rigid, while the lower end 200 is flexible. In another embodiment, the drop cover is configured as more than one piece, such that two or more sections of the drop cover can be displaced. FIG. 1B illustrates an example of a drop cover having two sections that are optionally interdigitated. In one use, a container inserted through the front face can distort or move the flap material until the container is within the interior 25, at which point the flap will return to an original configuration, i.e., one covering at least a portion of the front side. In an alternative, the drop cover can be moved away from the entryway so that a container can be inserted into the interior space, as will be described below. The point being that the drop cover should be configured to protect the mouth of a container and be able to accommodate in some way the ability to insert the container into the interior space.

When the drop cover is a rigid or semi-rigid device, it is possible for a container being inserted into the interior space to be tilted to a certain angle in order to avoid the drop cover. This would allow the drop cover to be stationary. If the container contents allow such tilting, this could be an acceptable option. However, if the container is full or if the drop cover dimensions do not permit, it may not be possible or desirable to tilt a container as it is placed in the interior space.

In one embodiment, a rigid or semi-rigid drop cover is moveable, such that it can be displaced from the entryway. In one embodiment, the drop cover is rotatably connected to the cover. This allows the drop cover to be lifted or pushed away from the entryway prior to, or as, a container is inserted. It can be beneficial if movement of the drop cover to a protective position and the insertion of a container 5 into the interior space 25 can be accomplished one-handedly. It would be further beneficial if the drop cover could remain displaced when a container is not within the interior space, so that it will be available for use at any moment, and further be moved into a proper position to protect the container after it is inserted.

One method for controlling the drop cover placement is the use of a linear actuator system 40. A linear actuator system can be located anywhere within or on a cover. This can include a drop cover 80 moveably engaged with the cover 20 and operably engaged with a linear actuator 42. The linear actuator system can further include a switch 43 that can move the linear actuator to displace the drop cover from the entryway 22 or replace the drop cover over the entryway. Typically, a linear actuator 42 is located within the interior space and secured with hangers 67. However, this is not required and it could be located on the outside of the cover. FIG. 2A illustrates a non-limiting example of an arrangement of a linear actuator system 40 having a linear actuator 42 operably engaged with a switch 43 that is further operably engaged with a spring mechanism 44, such as, for example, a helical spring or bending spring. The spring mechanism can bias the switch towards the entryway 22, which can push the linear actuator towards the drop cover, holding the drop cover in a rotated or otherwise displaced position. Put simply, the linear actuator can prop open the drop cover. When a container is inserted, the switch can be used to overcome the bias of the spring, and move the linear actuator away from the entryway, which causes the drop cover to be moved back into position over the entryway. In a further embodiment, a retaining mechanism 41 can be used to secure the switch in a position that keeps the drop cover over the entryway. This is just one example of a linear actuator system 40 that could be used with the embodiments of the subject invention. In a particular embodiment, the linear actuator holds the drop cover in an open position for insertion of a container. Once a container is inserted into the interior space, the switch can be manually moved to simultaneously move the linear actuator and close the drop cover. The entire process could be performed with one hand. A skilled artisan would be knowledgeable about many other types of actuator systems. Such variations that achieve the same results are within the scope of the subject invention.

A linear actuator system 40 can be further modified to permit the drop cover 80 to be automatically controlled. This could eliminate the use of a switch or the switch could be retained as an alternative option to the automatic system. Ideally, the drop cover could be controlled by the action of inserting or removing a container from the interior space 25. With such a system, the container could be used to control the position of the drop cover over the entryway, providing a more automatic system.

To achieve automatic control, the linear actuator system can be operably attached to a mechanism that allows a container inserted into the interior space 25 to activate, or deactivate, the linear actuator, thereby controlling the position of the drop cover. In one embodiment, the linear actuator 42 is operably connected to a first lever 46. The first lever can be used to make contact with a container. The operable connection between the linear actuator 42 and the first lever can be direct or can, alternatively, be an indirect connection, such that additional direct connections or a remote connection, e.g., magnetic connection, is used between the first lever and the first actuator arm. Ideally, contact of the first lever 46 with a container will activate the linear actuator 42 to close the drop cover 80. It can be most advantageous for a first lever and any associated connections to be located within the interior space. However, this is not required and some or all of the components could be located outside the cover.

In one specific embodiment, a compound lever system 45 is utilized to control the action of the drop cover 80 with the aid of a container 5. The compound lever system can convert the force exerted against one lever into an action that activates the linear actuator. Referring to FIGS. 2B, 3, 4, and 8, it can be seen that, in this specific embodiment, multiple levers are used to change a direction of force to control the drop cover. The first lever 46, which can be classified as a “first order” lever, can be operably engaged with a spring mechanism 44, which biases an effort end 47 of the first lever towards the entryway 22 and the spring can further act as a fulcrum point for the first lever, non-limiting examples, of which, are shown in FIGS. 3, 4, and 8. A load end 48 of the first lever 46 can be further operably connected to a push rod 49. The push rod can further be operatively engaged with the second effort end 51 of a second lever 50. The second lever can also be a first order lever such that there is also a fulcrum 53 and a second load end 52, where the load end of the second lever 50 can be operatively connected, such as with a rotatable connection, to the linear actuator 42.

With this specific embodiment, when a container is inserted into the interior space it can push against the load end 47 of the first lever 46, causing it to push that end towards the rear side 250 of the cover 20. When this happens, the load end 48 exerts force against the push rod 49 causing it to exert force against the second effort end 51 of the second lever 50, rotating on the fulcrum 53. This rotation causes the second load end 52 to move towards the rear side 250 of the cover, which, in turn, causes the linear actuator 42 to be pulled into the cover 20, allowing the drop cover 80 to move into a protective position over the entryway and covering the mouth of the container inserted into the interior space.

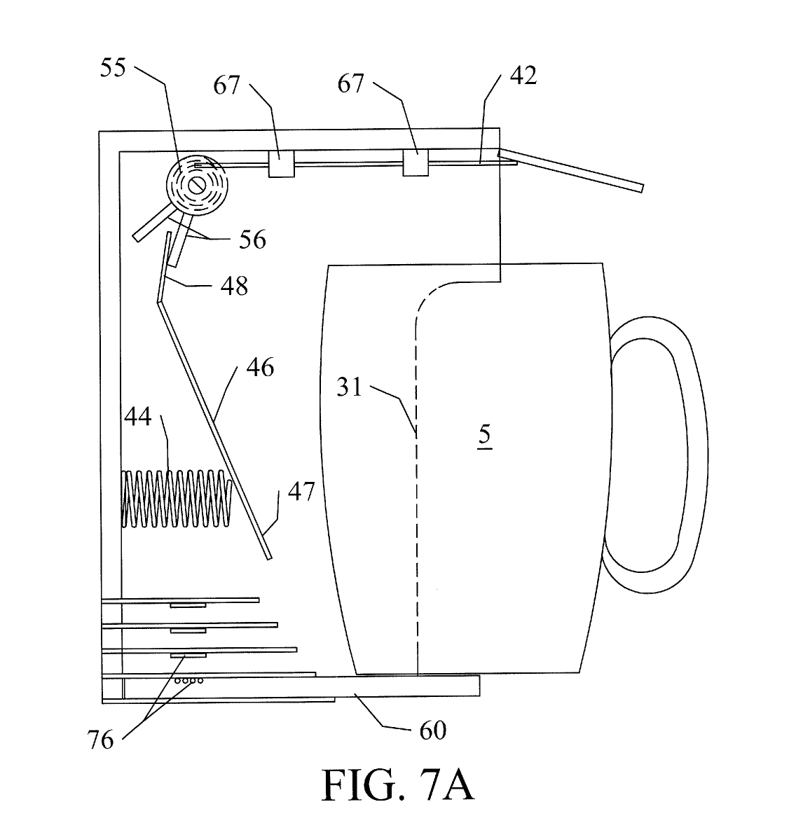

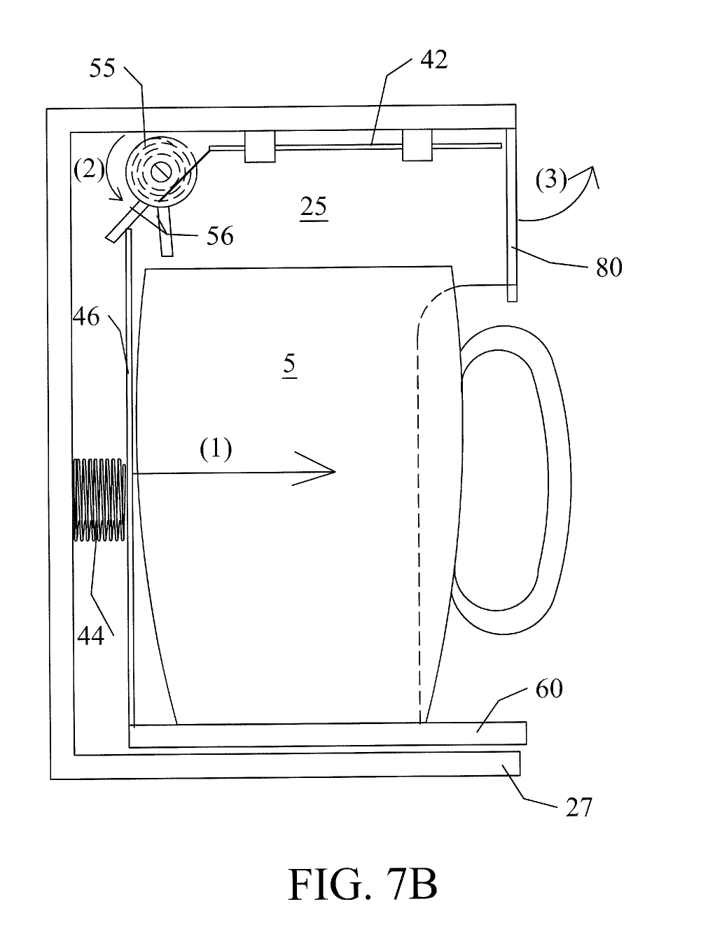

An alternative embodiment utilizes a spool 55 to which the linear actuator 42 is operably connected. FIG. 7B shows an example of an embodiment having a spool. The spool can be spring biased to one position. The spool can further have at least one leg 56 against which the first lever 46 can operate. As described above, the first lever can be operably connected to a spring mechanism 44 that biases the effort end 47 of the first lever towards the entryway 22, as discussed above. A container 5 inserted into the interior space 25 will exert force against the effort end 47 of the first lever. This can rotate the load end 48 against the leg 56 forcing the spool to turn, for example, counter clock-wise. The attachment of the linear actuator 42 to the spool causes the linear actuator to be pulled towards the rear side 250 of the cover 20 when the spool turns. As long as the container remains against the first lever, the spool will remain turned and the linear actuator will not force open the drop cover. FIG. 7B illustrates how removing the container causes the spring bias of both the spring mechanism 44 (1) and the spool 55 ((2) to force the effort end 47 of the lever to advance towards the entryway again, releasing the force against the leg 56 and allowing the spool to return to the original biased position, with the drop cover held open (3).

In an alternative embodiment, which can also be understood by FIG. 7, the first lever 46 is slidably attached to the cover, by any method known in the art, within interior space and is not spring-biased. The spool can have two appropriately spaced legs 56 between which the load end 48 of the lever can be disposed. When the container exerts force against the effort end of the lever, the load end pushes against a leg to cause the spool to rotate, again, for example, counter-clockwise. This pulls the linear actuator into the cover 20 so the drop cover 80 moves into a protective position over the entry way 22. When the container is removed and force is not exerted on the leg, the spring-bias of the spool causes it to rotate back to the original position, with the linear actuator forcing the drop cover out of the entry way. A second leg on the spool can contact the load end of the lever as the spool turns to help move the effort end 47 of the lever towards the entryway to make contact with a container.

In still another embodiment, the spring-biasing of the lever and spool can be reversed. This can allow the spool to move freely and a spring-mechanism 44 attached to the first lever, as shown in FIG. 7A, causes rotation of the spool and movement of the linear actuator in and/or out of the cover. The spool can have two legs 56 against which the load end of the lever can operate to rotate the spool when a container is inserted or removed from the interior space.

In yet another embodiment, the spool can have an over-the-center mechanism that causes it to snap into one or another rotated position as the load end of the first lever exerts force against them. In this embodiment, the first lever can again be spring-biased, but does not have to be, since the rotation of the spool and the attached legs can operate to keep the effort end 47 of the lever near to the entryway when a container is not within the interior space. FIGS. 7A and 7B illustrate an embodiment having a spool that can be configured according to any of the above-disclosed embodiments. To be clear, the drop cover can, but is not required, to be fixedly attached to the linear actuator.

The above-described examples should not be construed as the only possible mechanisms or methods by which the drop cover can be moved into and out of position against the front side. It will also be understood that more than one drop cover can be used with the embodiments of the subject invention. Therefore, more than one mechanism or system for controlling a drop cover can also be used. A person with skill in the art would be knowledgeable about and be able to create numerous types of mechanisms that can be used to effect movement of a drop cover. The advantages of using the mechanisms described above, or similar mechanical-based systems, is that they do not require electrical contact and can be used under almost any conditions, indoors or outdoors. However, there is no reason why a linear actuator or any other device for moving a drop cover could not be operated electrically, hydraulically, magnetically, pneumatically, or by any other method or system. Thus, it should be understood that such variations, which provide the same function, in substantially the same way, with substantially the same result, are within the scope of this invention.

When a container is inserted into the interior space 25, it can sit on a floor panel 60 that forms the lower end of the cover. In one embodiment, some part of the floor panel is contiguous with the walls 28 or 29 of the cover 20, such that the position of the floor panel is substantially fixed, which also fixes the volume of the interior space. When a container is inserted into the interior space it can push against the spring-biased first lever 46, as it rests on the floor panel, to hold the first lever in place and the drop cover closed.

In an alternative embodiment, the floor panel 60 can be operatively connected to the first lever 46, as shown in the example in FIG. 7B. With this embodiment, the actions and movements of the first lever can also affect the position of the floor panel relative to the cover. For example, when the effort end 47 of the spring-biased first lever 46 is directed towards the entryway, as discussed above, the floor panel can also be positioned closer to or even extending out of the entryway, such as shown in FIG. 1B. When a container is inserted into the interior space 25, it can push against the first lever pulling the floor panel in as the container sits on it, keeping the drop cover closed.

The spring-bias of the first lever can exert force that causes the combined first lever and floor panel to be pushed towards the entryway when the container is removed. In a further embodiment, a spool 55 employing an over-the-center biasing mechanism can be used to maintain the first lever 46 and floor panel 60 in the interior space when a container is placed thereon. With this embodiment, the load end 48 of the first lever can be positioned between two legs 56 on the spool. When the container is inserted and pushed against the first lever, it engages the load end 48 with a leg of the spool causing the spool to rotate until sufficient force is applied to the over-the-center biasing mechanism to “snap” the spool into a new rotated position. The leg 56 exerts force against the load end, preventing the first lever from moving towards the entryway.

Upon removal of the container from the cover, the floor panel can return to a position close to or extending from the entry way. When the floor panel moves towards the entry way, it causes the load end 48 to engage with another leg on the spool, which in turn causes it to rotate in the opposite direction until sufficient force is applied to the over-the-center mechanism to “snap” the spool into the previous position. Any of a variety of methods and devices can secure the position of the container and floor panel in the cover until such time that the container is removed. In one example, the spring that biases the first lever can be gauged to provide sufficient force to move the first lever towards the entryway only when a container is not placed on the floor panel.

In another embodiment, the cover 20 can include one or more supports 27 on which the floor panel can rest. A support can extend across any portion of the lower end 200 of a cover. It can be connected to one or both sidewalls 29 and/or to the rear wall 28 and can have any desirable or necessary dimensions. FIG. 7B illustrates an example of a support connected to at least one sidewall and to the rear wall and further has dimensions approximately equivalent to the dimensions of the roof 30. Other examples can have a support that is less extensive or that is less connected than the one shown in FIG. 7B. Such variations are within the scope of this invention.

While the embodiments described above can be designed for use with specific container types or sizes, a protective hutch 10 of the subject invention can be a more beneficial if it has universal operability. The embodiments of a drop cover described above can allow numerous types of containers to be inserted into the interior space. However, the ability of the drop cover to protect the mouth of the container will depend upon whether the container size allows the mouth to be located behind the drop cover when in the interior space, as shown, for example, in FIGS. 5 and 6. Should a container be too short, the drop cover may not extend far enough to protect the mouth of the container. If the drop cover is made too large, meaning it extends too far towards the lower end 200, it might interfere with the ability to grasp the container when inside the cover. Therefore the ability to adjust the size of the interior space can be advantageous and allow a greater number of container styles and sizes to be used with the protective hutch 10 embodiments of the subject invention.

In one embodiment, the floor panel 60 is moveable within the interior space. More specifically, the floor panel can be moved further from or closer to the roof, so that the drop cover 80 can protect the mouth of practically any container that can fit between the sidewalls and within the interior space. In a further embodiment, the interior space 25 of the cover 20 can be configured with multiple supports 27, one example of which is shown in FIGS. 1D, 2A, 3, and 6. The floor panel can be engaged with one or more supports to adjust the size of the interior space available to a container. FIG. 3 shows one example of a floor panel 60 engaged with a support at the lowest end 200 of a cover. The container shown inserted therein can be placed on the floor panel and still have the mouth protected by the drop cover when emplaced over the entryway. FIG. 6 shows another example of a floor panel engaged with two supports 27 that are closer to the upper end 100 of the cover. The container shown inserted therein is shorter than the container shown in FIG. 3. However, the ability to move the floor panel ensures that the drop cover can still protect the mouth of the shorter container.

A support can assume any of a variety of configurations that are capable of supporting a floor panel and a container. Typically, though not exclusively, the supports and floor panel can be engaged similarly to a mortis and tenon fashion, whereby one slides into or past the other. In the embodiments shown in FIGS. 1D, 2A, 3, and 6, a support is a projection from a sidewall and/or the rear wall. In one embodiment, there are multiple supports appropriately spaced to receive one end of a floor panel between them. Alternatively, the supports can be formed as linear channels within the sidewalls and/or rear wall, as shown in the example in FIG. 1C. Thus, a floor panel can still be supported by two supports on the upper end 100 and lower end 200 of the floor panel.

To assist with insertion of a floor panel between two supports, it can be helpful for the different levels of supports to be discernable both visibly and non-visibly. Since a protective hutch 10 of the subject invention can be used in numerous locations, it may not always be possible to visibly adjust the height of a floor panel. Thus, an ability to adjust the floor panel by tactile indications would be beneficial in some locations or environments.

In one embodiment, the supports are graduated in length from shorter to longer towards the lower end, such that a floor panel can be inserted into the interior space 25 above the support 27 at the most upper end 100 of the cover 20, which can be shorter than the support below it. By slowly pulling the floor panel towards the entryway 22, the rear side 250 of the floor panel 60 will fall progressively down the graduated supports. This can be likened to pulling a board down a flight of stairs where the end of the board hits each stair progressively. When the rear side 250 of the floor panel reaches the desired level, the floor panel can be held generally perpendicular to the rear wall and pushed towards the rear wall to be engaged between two supports—the one it rests on and the one it immediately dropped down from. In this way, the floor panel can be easily adjusted even if the interior space is not viewable.

To prevent sliding of the floor panel away from the support, one or more anti-slide features can be used. An anti-slide feature can be a device, material, or surface feature that inhibits movement of the floor panel relative to the supports. In one embodiment, a nip 62 and a detent 64 can be used to help secure a floor panel in place. Generally, a nip is a small surface projection and a detent is a corresponding depression within another surface. When the surfaces are brought together, the nip and detent engage to inhibit them from sliding apart. A nip and detent can be of any size or shape and multiple ones can be used as well. In one embodiment, a nip and detent are used between a floor panel and a support, whereby sliding the floor panel between two supports can engage one or more nips with one or detents to inhibit the floor panel from sliding out from between the two supports. However, upon application of sufficient force, the one or more nips can be disengaged from the one or more detents and the floor panel adjusted if necessary. A variety of anti-slide features are known in the art and such variations are within the scope of this invention.

A particular advantage that can be realized with the embodiments of a protective hutch 10 of the subject invention is the ability to passively control or preserve the temperature of a substance within a container. In one embodiment, the sidewalls, roof, and floor panel can have insulation properties or features 300 that help maintain or at least reduce the rate of change in the temperature of a substance in a container, either cold or hot as the case may be. This can be beneficial, for example, in keeping a beverage hot or cold. It can also function to protect the contents of a container from environmental conditions. One particular use could be to help maintain the temperature of a beverage by insulating it, at least partially, from environmental temperatures or holding the temperature of the container stable within the interior space.

A protective hutch could also be used to actively maintain or even achieve a desired temperature for a substance in a container. For example, the protective hutch can include a temperature control element, such as, for example, a heating or cooling element that maintains a specific temperature within the internal space. In a specific embodiment, the floor panel 60 contains a temperature element 70. A container placed on the floor panel can absorb radiant heat or cold and subsequently radiate it to a substance in the container. A container can contact the temperature element directly or indirectly through the floor panel.

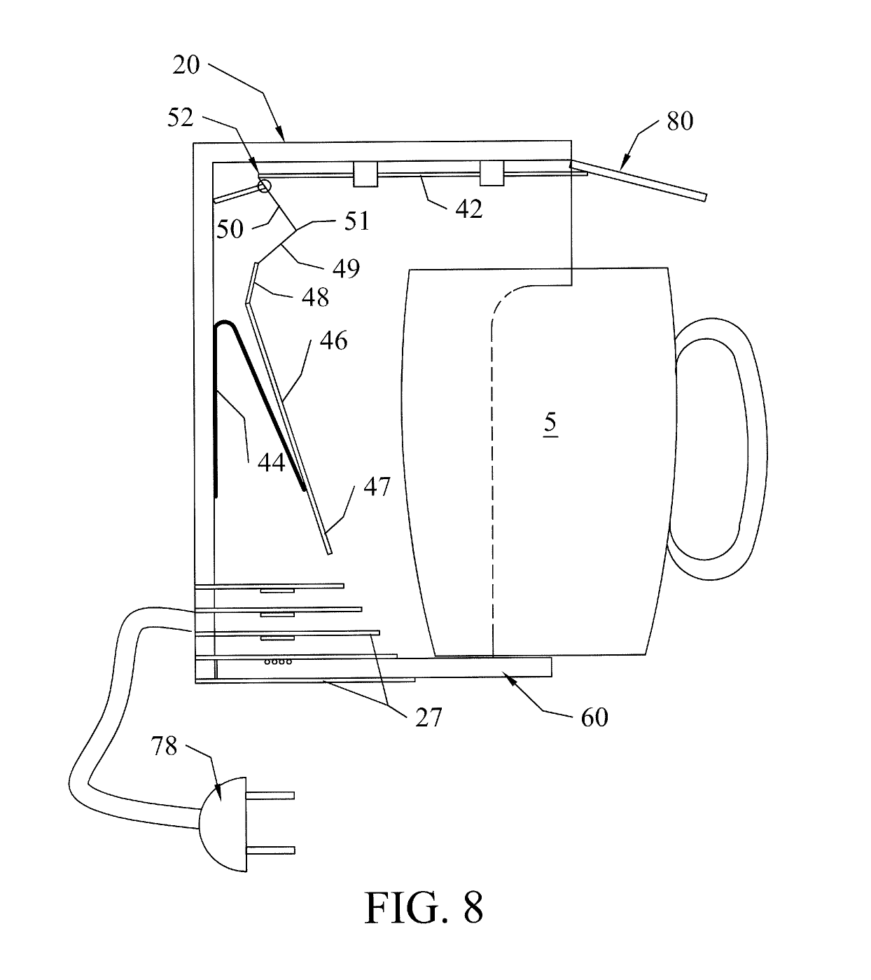

A temperature element can be AC, DC, or AC/DC powered. In one embodiment, a floor panel has a battery compartment 72, for example, as shown in FIG. 4. In a more specific embodiment, the floor panel can be configured to operatively engage with contacts 76 in the cover and/or supports 27. Ideally, when the floor panel is engaged between two supports, the contacts 76 in the floor panel will operatively engage with contacts in the supports to complete the electrical current to the temperature element. In a particularly advantageous embodiment, the contacts can also act as nips and detents to not only complete an electrical current, but also secure the position of a floor panel. Alternatively, a floor panel can have an electrical cord 78, as shown in the example in FIG. 8, attached to it that operates the temperature element. There can also be temperature controls and an on/off switch 77 to control the temperature element.

Temperature elements are well-known in the art. A skilled artisan would be able to determine any number of arrangements for a temperature element useful with the embodiments of the subject invention. A skilled artisan would also be able to determine the most efficacious way to incorporate such a temperature element with a protective hutch of the subject invention. Thus, while a temperature element as described herein is located within a floor panel, a skilled person trained in the art would understand how to install a temperature element anywhere in a protective hutch. Such variations which perform the same function, in substantially the same way, with substantially the same result are within the scope of this invention.

A protective hutch according to the subject invention can be used to hold and protect the contents of a container. The advantageous feature of a drop cover that can be automatically controlled by the action of inserting or removing a container from the protective hutch provides the device with single-handed operation. The adjustability of the floor panel provides a further advantage of making the device adaptable to practically any size container. A protective hutch can be installed as a permanent fixture or it can be designed for table top use or even used in a vehicle. The ability of the device to operate without an electrical connection and the one-handed operation make it useful in almost any location.

The examples and embodiments described herein are for illustrative purposes only and that various modifications or changes in light thereof will be suggested to persons skilled in the art and are to be included within the spirit and purview of this application.

Any reference in this specification to “one embodiment,” “an embodiment,” “example embodiment,” “further embodiment,” “alternative embodiment,” etc., is for literary convenience. The implication is that any particular feature, structure, or characteristic described in connection with such an embodiment is included in at least one embodiment of the invention. The appearance of such phrases in various places in the specification does not necessarily refer to the same embodiment. Further, when a particular feature, structure, or characteristic is described in connection with any embodiment, it is within the purview of one skilled in the art to affect such feature, structure, or characteristic in connection with other ones of the embodiments.

The invention has been described herein in considerable detail, in order to comply with the Patent Statutes and to provide those skilled in the art with information needed to apply the novel principles, and to construct and use such specialized components as are required. However, the invention can be carried out by specifically different equipment and devices, and that various modifications, both as to equipment details and operating procedures can be effected without departing from the scope of the invention itself. Further, although the present invention has been described with reference to specific details of certain embodiments thereof and by examples disclosed herein, it is not intended that such details should be regarded as limitations upon the scope of the invention except as and to the extent that they are included in the accompanying claims.

We claim:

1. A protective hutch comprising:
a cover that defines an interior space and a front side comprising an entryway into the interior space;
a drop cover moveably connected to the cover;
a floor panel;
at least one support within the interior space for operatively engaging with the floor panel to adjust the interior space;
a linear actuator engaged with the drop cover that, when activated, holds the drop cover away from the entryway and when deactivated causes the drop cover to move into a protective position over at least a portion of the entryway; and
a first lever operatively attached to the linear actuator that, when contacted by a container deactivates the linear actuator.

2. A protective hutch according to claim 1, wherein the entryway comprises most of the front side of the cover.

3. A protective hutch according to claim 1, wherein the drop panel is rotatably moveable.

4. A protective hutch according to claim 1, further comprising a cut-out in the cover that is further protected by the drop cover when the linear actuator is deactivated.

5. A protective hutch according to claim 1, further comprising a spring mechanism operatively engaged with the first lever, wherein the spring mechanism biases the first lever towards the entryway.

6. A protective hutch according to claim 5, wherein the first lever and the linear actuator are operatively attached by at least one of a compound lever system and a spring-biased spool.

7. A protective hutch according to claim 6, further comprising at least two supports that are graduated in length.

8. A protective hutch according to claim 7, further comprising one or more anti-slide features incorporated with at least one of a floor panel and supports.

9. A protective hutch according to claim 6, further comprising a temperature control element.

10. A protective hutch according to claim 9, wherein the temperature control element is incorporated into the floor panel.

11. A protective hutch according to claim 10, wherein the temperature control element is electrically powered.

12. A protective hutch according to claim 11, further comprising one or more contacts in the floor panel and one or more contacts in the supports, such that when the floor panel is operatively engaged with the supports, the contacts in the floor panel and the contacts in the supports are also operatively engaged to complete an electric current.
